(19) United States
(12) Patent Application Publication
(10) Pub. No.: US 2023/0290636 A1
(43) Pub. Date: Sep. 14, 2023

(54) IN SITU DOPING OF IRONS INTO MOS2 TOWARD TWO-DIMENSIONAL DILUTE MAGNETIC SEMICONDUCTORS

(71) Applicant: THE TRUSTEES OF THE STEVENS INSTITUTE OF TECHNOLOGY, Hoboken, NJ (US)

(72) Inventors: Eui-Hyeok Yang, Fort Lee, NJ (US); Shichen Fu, Hoboken, NJ (US); Kyungnam Kang, Edgewater, NJ (US)

(73) Assignee: THE TRUSTEES OF THE STEVENS INSTITUTE OF TECHNOLOGY, Hoboken, NJ (US)

(21) Appl. No.: 18/008,126

(22) PCT Filed: Jun. 4, 2021
(86) PCT No.: PCT/US2021/036034

§ 371 Date: Dec. 2, 2022

Related U.S. Application Data
(60) Provisional application No. 63/034,812, filed on Jun. 4, 2020.

(51) Int. Cl. H01L 21/02; C01G 39/06; C23C 16/30; C23C 14/08; C23C 16/40; C23C 28/04; C23C 16/56; C23C 14/30; H10N 50/10

(52) U.S. Cl. CPC H01L 21/02568; C01G 39/06; C23C 16/305; C23C 14/083; C23C 16/406; C23C 28/042; C23C 16/56; C23C 14/30; H01L 21/0262; H10N 50/10; C01P 2002/54; C01P 2006/40; C01P 2006/42; C01P 2004/04; C01P 2002/77

(57) ABSTRACT

A method for producing doped, van der Waals ferromagnetic materials is disclosed. Such materials can take the form of monolayer iron-doped transition metal dichalcogenides. Such materials are useful for the manufacture of semiconductors, as high curie temperatures are achieved (i.e., those exceeding room temperature), which allows for the preservation of useful ferromagnetic and semiconducting properties across a wider range of conditions.

### CROSS-REFERENCE TO RELATED APPLICATION

This application claims priority to U.S. Provisional Patent Application Ser. No. 63/034,812 filed Jun. 4, 2020, the entire disclosure of which is incorporated herein by reference.

### FIELD OF THE INVENTION

The present invention relates to materials useful as semiconductors with a ferromagnetic property, and more specifically, to iron-doped transition metal dichalcogenide monolayers with ferromagnetism stable at or above room temperature.

### BACKGROUND OF THE INVENTION

Semiconductors possess enormous utility in the computing fields, and electronics in general. Specifically, dilute magnetic semiconductors (DMSs) are a class of semiconductor materials that exhibit both ferromagnetism and semiconductor properties, which include Mn-doped Pb₁₋ₓSnₓTe and GaAs among others. Of particular interest, DMS materials allow for the manipulation of quantum spin states, which makes them promising candidates for a variety of applications. However, current implementations of such technology are not viable for practical applications, as the useful ferromagnetic properties of known DMS materials degrade at temperatures well below room temperature.

### SUMMARY OF THE INVENTION

The present invention provides for in situ doping of irons into MoS₂, which facilitates the fabrication of two-dimensional (2D) dilute magnetic semiconductors that retain their useful properties below, at, and above room temperature.

By the fabrication methods of the present invention, the class of available ferromagnetic 2D materials has been expanded to include the iron doped DMS material of the present invention, the first in its class with Curie temperature (T_{C}) above room temperature. Stable DMS at normal operating temperatures will open new opportunities towards realizing on-chip magnetic manipulation at room temperature.

Its capability of controlling quantum spin states makes DMS a promising candidate for spintronics applications. Spintronic devices control the quantum spin state, which enables almost total spin polarization. This would allow for the development of spin transistors, which rely on the ability of electrons to exhibit one of two states of spin. In turn, the electrons set in particular states of spin may be used to store information.

As such, previously proposed magnetically-sensitive devices are made out of magnetic semiconductors. However, such materials have a Tc at and above which the ferromagnetic materials (FM) lose their permanent magnetic field. The previous highest observed ferromagnetic T_{C} was 110 K in Mn-doped GaAs, which is still far below room temperature. Such low ferromagnetic T_{C} prevents DMSs from realizing their desirable properties in practical applications.

Doping transition metal impurities into transition metal dichalcogenide (TMD) monolayers obtains atomically thin DMSs. Such new 2D DMS systems provide potential opportunities to achieve a ferromagnetic T_{C} close to or higher than room temperature.

Vanadium-doped compounds, such as V:MoTe₂ and V:WSe₂, have been shown to possess a Tc higher than room temperature. However, these materials were fabricated using mechanical exfoliation before post-growth doping, which severely limits their practical applications due to their lack of scalability, in the case of V:MoTe₂, and low-yield in fabrication, in the case of V:WSe₂. The V:MoTe₂ requires a post-growth method, which is time consuming, and the V:WSe₂ requires a solution-based synthesis to obtain the material. Such solution-based synthesis has a low yield and cannot be scaled up for practical applications.

In contrast, the present invention involves utilizing a low-pressure chemical vapor deposition (LPCVD) growth method to synthesize Fe:MoS₂ monolayers, while simultaneously doping iron into MoS₂. The LPCVD-grown 2D materials have a high potential to be scaled up. Furthermore, this is accomplished while also achieving a DMS with a Tc above room temperature.

Specifically, in one embodiment, the present invention provides for the creation of in situ doped Fe:MoS₂ monolayers, which constitute an entirely new class of iron-based van der Waal s ferromagnets with semiconducting properties at room temperature, as well as high magnetic field strength. These monolayers displayed, at room temperature, comparable magnetic field strength to their metallic counterparts that are based on monolayers of CrI3 or CrBr3 at cryogenic temperatures.

These properties are conducive to applications such as on-chip magnetic manipulation of quantum states. The present invention enables applications relating, for instance, to such categories as quantum information science, and minimizing bit storage in spintronics, spintronic devices (spin-injection sources) and memory devices.

In particular, two-dimensional (2D) spintronic devices, including 2D spin-transfer torque magnetoresistive random-access memory (2D STT MRAM) can be developed. In this vein, a 2D STT-MRAM is presented, which is a solid state magnetic memory in the form of a magnetic tunnel junction (MTJ). The STT-MRAM comprises three elements: the free layer, the fixed layer and the tunnel barrier.

Further applications include 2D devices and/or applications including controllability via strain and gating, heterostructures, magnetic sensors, terahertz magneto-optical devices, multiferroics and topological quantum computing.

### BRIEF DESCRIPTION OF THE DRAWINGS

For a better understanding of the present invention, reference is made to the following detailed description of various exemplary embodiments considered in conjunction with the accompanying drawings, in which:

FIG. 1 is a schematic flow diagram showing a manufacturing process for materials made in accordance with an embodiment of the present invention;

FIG. 2A is an atomic force microscope (AFM) image of a material prepared in accordance with an embodiment of the present invention;

FIG. 2B is the AFM line scan across the sample (white line) drawn in FIG. 2A on the Fe:MoS₂ monolayer;

FIG. 3A is a schematic diagram of the crystal structure of a Fe:MoS₂ monolayer prepared in accordance with the present invention;

FIG. 3B is a top view of the schematic diagram of FIG. 3A;

FIG. 4 is a series of graphs corresponding to a STEM intensity scan;

FIG. 5 depicts the evolution of PL intensity as a function of temperature for a compound prior to doping;

FIG. 6 depicts the evolution of PL intensity as a function of temperature for the compound of FIG. 6 after doping in accordance with an embodiment of the present invention;

FIG. 7 is a schematic diagram illustrating operating principles of a 2D STT MRAM device made in accordance with an embodiment of the present invention;

FIG. 8 is a conceptual cross-sectional schematic of a 2D STT MRAM device made in accordance with an embodiment of the present invention;

FIG. 9A is a schematic diagram illustrating operating principles in accordance with one embodiment of the present invention;

FIG. 9B is another schematic diagram illustrating alternative operating principles in accordance with one embodiment of the present invention;

FIG. 10 is a schematic diagram illustrating the operation of a device made in accordance with an embodiment of the present invention;

FIG. 11 is a schematic diagram illustrating the operation of a device made in accordance with an embodiment of the present invention;

FIG. 12 is a schematic diagram illustrating the operation of an MRAM device;

FIG. 13 is a schematic diagram illustrating the operation of an alternative MRAIVI device, useful in connection with embodiments of the present invention;

FIG. 14 is a schematic diagram illustrating the operation of a device made in accordance with an embodiment of the present invention; and

FIG. 15 is a schematic diagram illustrating the operation of a device made in accordance with an embodiment of the present invention.

### DETAILED DESCRIPTION OF EMBODIMENTS OF THE INVENTION

Various embodiments of the present invention are disclosed herein; however, it is to be understood that the disclosed embodiments are merely illustrative of the invention that can be embodied in various forms. In addition, each of the examples given in connection with the various embodiments is intended to be illustrative, and not restrictive. Further, the figures are not necessarily to scale, and some features may be exaggerated to show details of particular components (and any size, material and similar details shown in the figures are intended to be illustrative and not restrictive). Therefore, specific details disclosed herein are not to be interpreted as limiting, but merely as a representative basis for teaching one skilled in the art to variously employ the disclosed embodiments.

Subject matter will now be described more fully hereinafter with reference to the accompanying drawings, which form a part hereof, and which show, by way of illustration, specific exemplary embodiments. Subject matter may, however, be embodied in a variety of different forms and, therefore, covered or disclosed subject matter is intended to be construed as not being limited to any exemplary embodiments set forth herein, it being understood that such exemplary embodiments are provided merely to be illustrative. Among other things, for example, subject matter may be embodied as methods, devices, components, materials, compositions or systems. The following detailed description is, therefore, not intended to be taken in a limiting sense.

Throughout the specification, terms may have nuanced meanings suggested or implied in context beyond an explicitly stated meaning. Likewise, the phrase “in one embodiment” as used herein does not necessarily refer to the same embodiment and the phrases “in another embodiment” and “other embodiments” as used herein do not necessarily refer to a different embodiment. It is intended, for example, that covered or disclosed subject matter includes combinations of the exemplary embodiments in whole or in part.

In general, terminology may be understood at least in part from usage in context. For example, terms, such as “and”, “or”, or “and/or,” as used herein may include a variety of meanings that may depend at least in part upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

In one embodiment, the present invention allows for creation of a 2D DMS that can be realized via in situ synthesis of iron-doped MoS₂ (Fe:MoS₂) monolayers. In alternate embodiments, other doped TMD compounds may be produced, such as those comprising WS₂, MoSe₂ and WSe₂, using the methods of the present invention. In one embodiment, the in situ doping and the growth of the material are simultaneously achieved via LPCVD growth. In one embodiment, Fe:MoS₂ monolayers are grown onto an SiO₂ substrate in this manner, while FeCl₃ (anhydrous) on a Si substrate can also be used as the Fe source for doping.

In one embodiment, prior to growth, a thin MoO₃ layer is prepared using physical vapor deposition (PVD) of e-beam-evaporated MoO₃ (e.g., in pellets) onto a Si substrate with thermal oxides of a suitable thickness (e.g., 300 nm-thick). Next, another SiO₂/Si substrate contacts the MoO₃-deposited substrate face-to-face. In alternate embodiments, SiC and sapphire substrates may be used for the MoO₃ and/or FeCl₃.

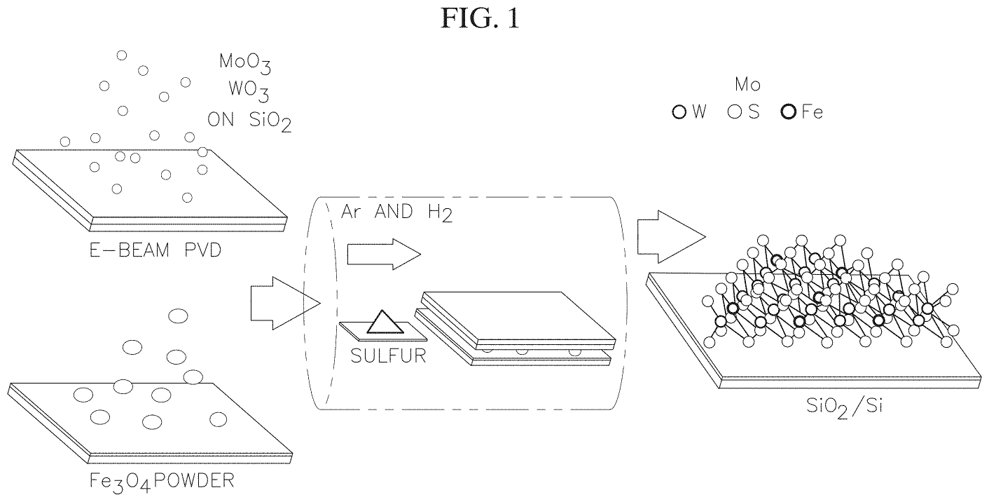

A manufacturing flow chart for obtaining Fe: MoS₂ monolayers is shown in FIG. 1. To grow Fe: MoS₂ monolayers onto the SiO₂/Si substrate, the Fe doping may be achieved in the following sequence: Fe₃O₄ particles are evenly cast onto the SiO₂/Si substrate before contacting the MoO₃-deposited substrate. In some embodiments, to ensure a uniform distribution of Fe₃O₄ particles, the substrate can be washed using deionized (DI) water so that a thin layer of water is created on the SiO₂ surface, prior to applying the Fe₃O₄ particles. After casting the particles, the substrate is then annealed at 110° C. or above for 5 min to 10 min on a hot plate. During the growth, the furnace can be heated up with a ramping rate of 18° C./min to 25° C./min and held for 15 min to 20 min at about 850° C. During the heating procedure, an argon gas (25 to 30 sccm) can be supplied at 300° C. to 400° C., and subsequently, a hydrogen gas (15 to 20 sccm of) may be delivered at 750° C. to 770° C. In one embodiment, Ar:H₂ is between 3:2 to 2:1. Sulfur may be supplied when the furnace temperature reaches 780° C. to 800° C. After the growth, Fe:MoS₂ monolayers are obtained.

Specifically, 2D iron-doped transition metal dichalcogenides are obtained by the aforementioned method. The substrate used can be varied (e.g., SiC or sapphire), or the doped monolayer may be transferred to another desired substrate when formed, as appropriate to the intended application.

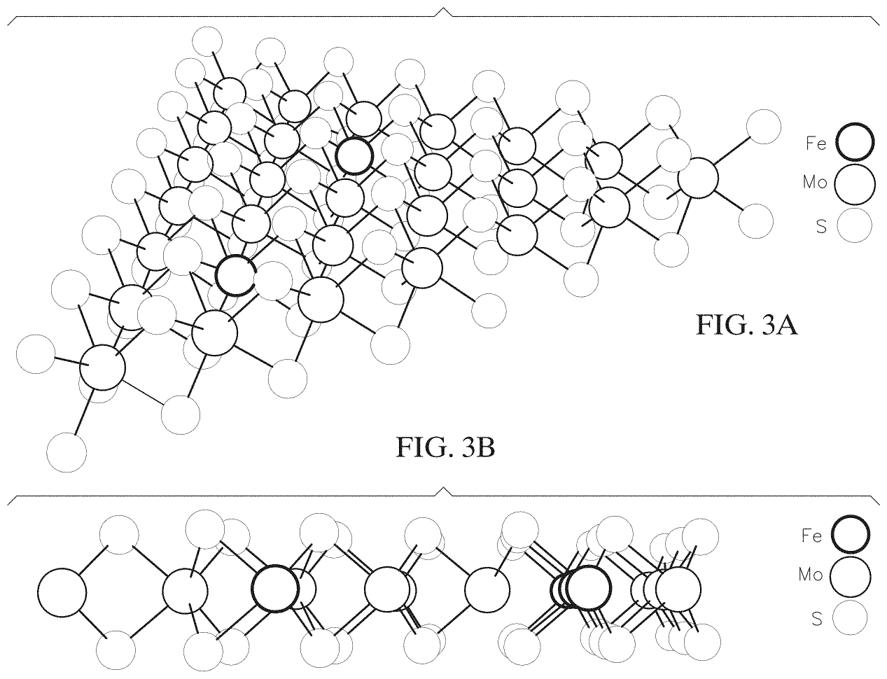

FIGS. 3A and 3B show schematics of the crystal structures of a Fe:MoS₂ monolayer in cross-sectional and top views, respectively.

The presence of Fe atoms in the MoS₂ lattice was verified using scanning transmission electron microscopy (STEM) and Raman spectroscopy. Photoluminescence spectroscopy revealed a new Fe-related emission at 2.28 eV in the Fe:MoS₂ monolayers that is stable up to room temperature.

This in situ synthesis of Fe:MoS₂ monolayers realizes a new class of iron-based van der Waals ferromagnets with semiconducting properties at room temperature. Using such methods one can readily fabricate an Fe:MoS₂ material-based spin transistor, and memory (magnetoresistive random access memory, i.e. MRAM) devices in the future.

The achievement of ferromagnetism in 2D crystals, combined with their rich electronics and optics, could open up numerous opportunities. The flexibility of the layer stacking process facilitates the creation of van der Waals heterostructures between layered ferromagnets and a diverse set of other 2D materials. In contrast to the traditional magnetic thin films, 2D materials largely decouple from the substrates, allow electrical control, are mechanically flexible, and are open to chemical functionalization. These attributes make 2D magnets accessible, engineerable, and integrable into emergent heterostructures for previously unachieved properties and applications.

In particular, the present invention can be used to develop 2D STT MRAM devices. While conventional STT MRAM devices use a metallic ferromagnet as a free layer, which demands high energy to change the direction of magnetization, the devices of the present invention can use Fe:MoS₂ in 2D STT MRAM, which will ensure much lower energy consumption. Furthermore, this 2D STT MRAM application provides room temperature operation, and can be applied to curved and bendable surfaces.

In an embodiment of the present invention, a 2D STT-MRAM is proposed, which includes a solid state magnetic memory in the form of a magnetic tunnel junction (MTJ). The STT-MRAM cell has a free layer, a fixed layer and a tunnel barrier. The free layer stores information in its magnetic state. The fixed layer provides a reference frame required for reading and writing.

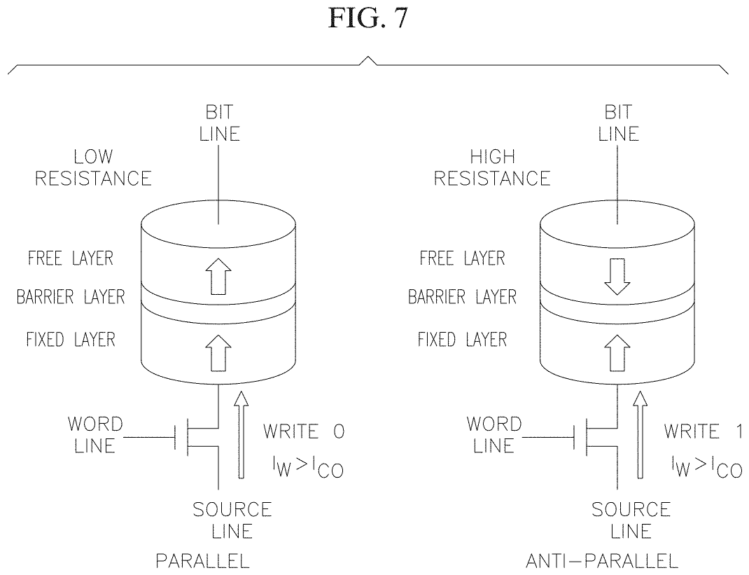

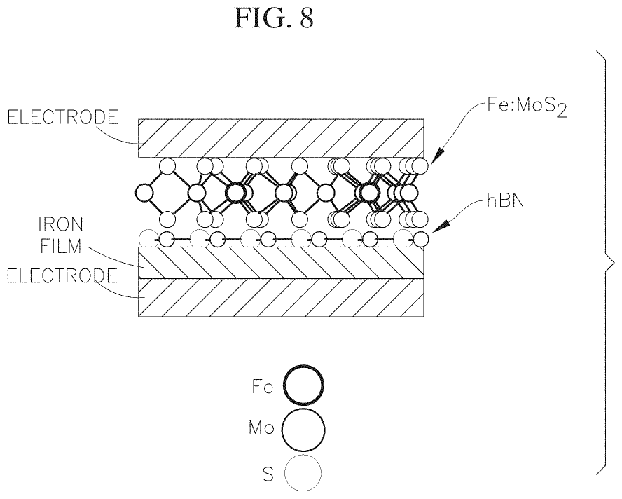

The STT-MRAM functionality is powered by the tunneling magnetoresistance (TMR) effect for the reading of memory and the STT effect for the writing to memory. This TMR effect causes the resistance of the MTJ to change dramatically, which enables the magnetic state of the free layer to be sensed and, thus, stored information to be read. FIG. 7 is a schematic illustration of the operating principle of the inventive STT-MRAM in parallel and antiparallel modalities. The STT effect permits electrons to flow through the MTJ to transfer spin angular momentum between the magnetic layers, resulting in a torque on the magnetization of the free layer. This action enables the magnetic state of the free layer to be changed if the torque is sufficiently strong, and thus information can be written. FIG. 8 shows a conceptual cross-section of one embodiment of the inventive 2D STT MRAM.

The free layer can be a 2D magnetic semiconductor layer, and the fixed layer can be made of another magnetic layer, which does not switch during the memory operation. The tunnel barrier is a thin (˜10 Å) insulating, non-magnetic layer between the free layer and the fixed layer. In one embodiment, the insulating layer is crystalline MgO. In another embodiment, the insulating layer (i.e., tunneling barrier) comprises hexagonal boron nitride.

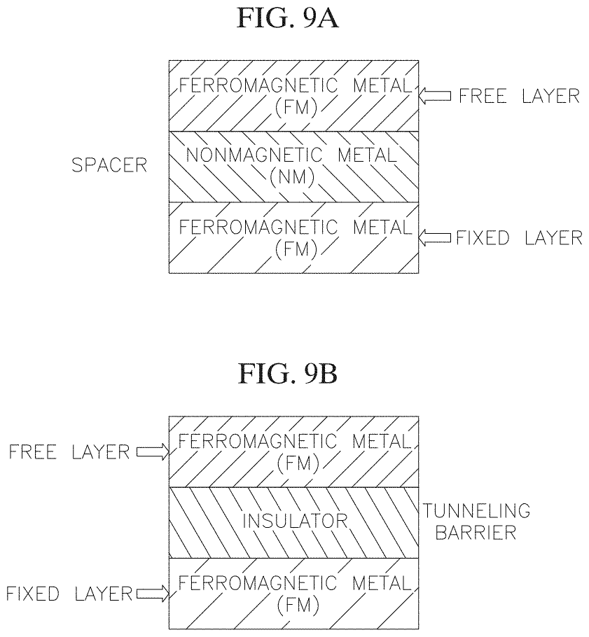

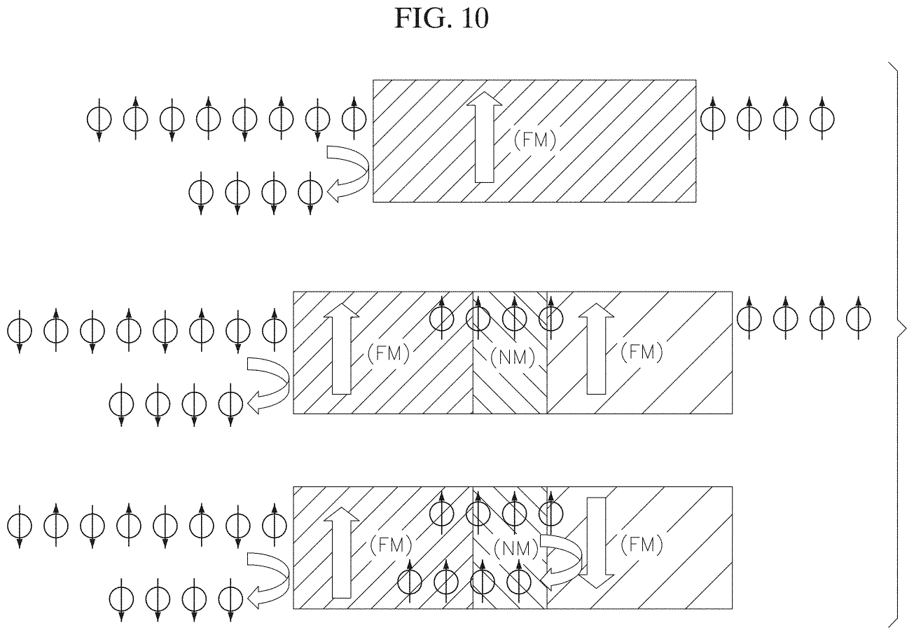

FIG. 9A shows a giant magnetoresistance (GMR) structure, wherein a nonmagnetic conductor is sandwiched between two FM. FIG. 9B shows a tunneling magnetoresistance (TMR) structure. The MTJ uses the TMR effect to operate. In such spin-transfer torque (STT) implementations, magnetization switching is induced by electric current.

The fixed layer has a fixed magnetization direction; the free layer can change its magnetization direction. A spacer (i.e., nonmagnetic metal) or tunneling barrier (insulator) is fixed between the two layers in GMR and TMR structures, respectively.

FIG. 10 is a schematic diagram illustrating working principles of magnetoresistance. Electrons with spin parallel to magnetization have weak scattering and low resistance. Electrons with spin antiparallel to the magnetization experience strong scattering and high resistance.

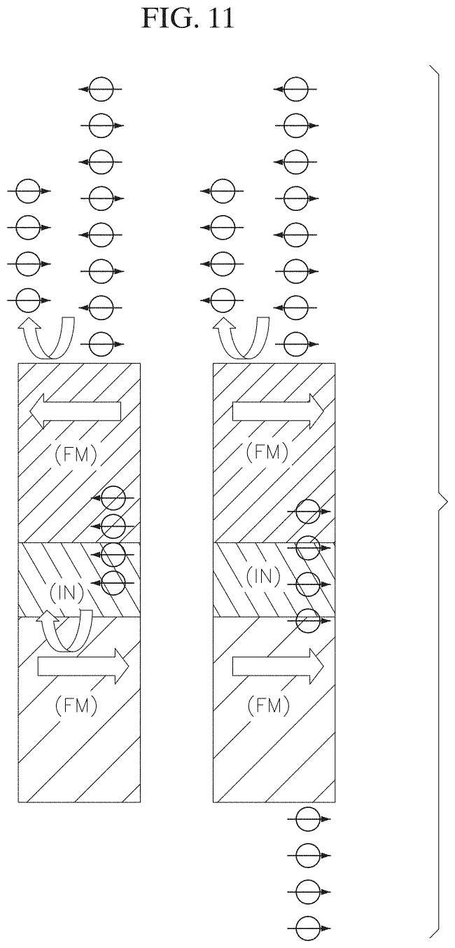

FIG. 11 is an illustration of the TMR effect for an MTJ. The magnetization direction of the free layer changes, while that of the fixed layer does not. In order to change the direction of magnetization in the free FM layer, the STT effect can be used. In such implementations, the orientation of a magnetic layer in a magnetic tunnel junction can be changed using a spin-polarized current. For instance, if a spin-up electron is provided to a downwardly magnetized FM, the direction of the magnetization changes to the upward direction.

Unlike ferromagnetic metals used in conventional STT-MRAM designs, Fe:MoS₂, a 2D ferromagnetic semiconductor with a lower coercivity field, requires much less energy to change its direction of magnetization. The 2D MTJ structure can be readily fabricated and integrated into the current STT-MRAM structure via placing 2D ferromagnetic semiconductor monolayer as the free layer.

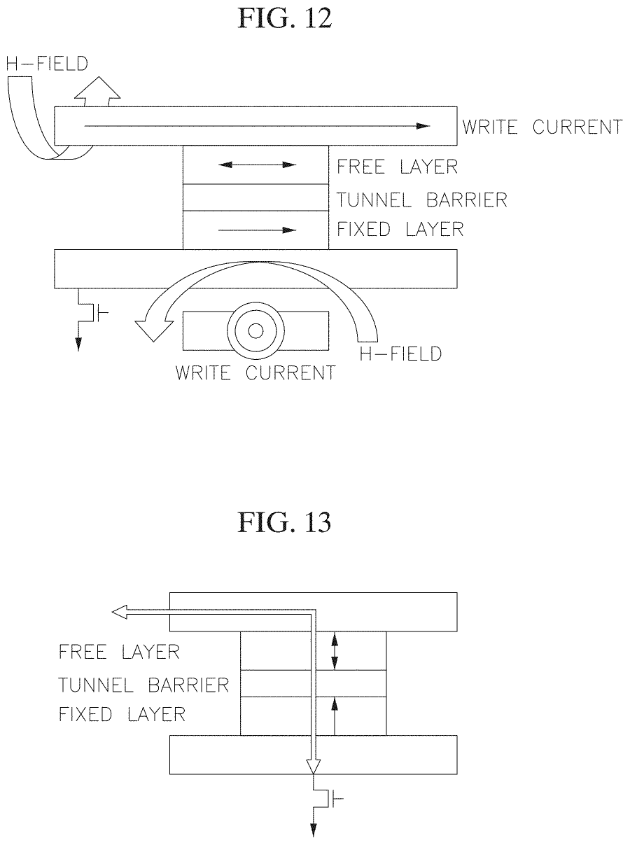

FIG. 12 illustrates an embodiment of MRAM in which a magnetic field is used for Toggle (i.e., Field) MRAM. In such embodiments, high electric currents and large amounts of energy are needed. Such embodiments also face limits with respect to scaling, due to the non-local magnetic field required.

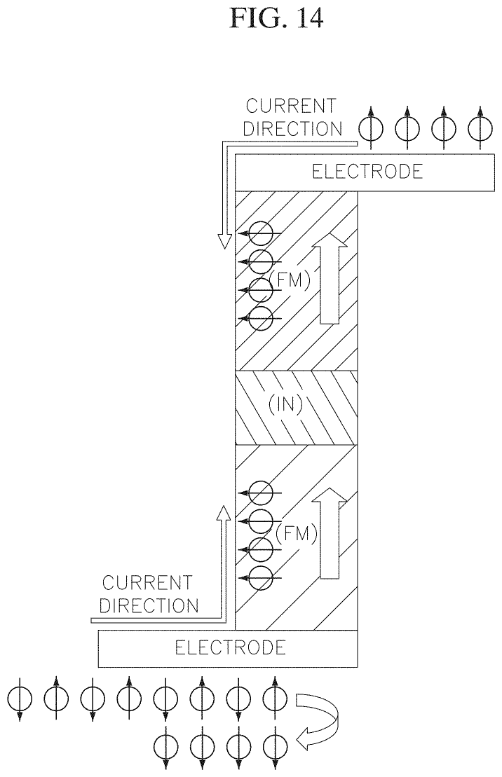

FIG. 13 shows a schematic diagram of a STT MRAM device, which operates using fast switching, small currents, which lends itself to low energy consumption. In an embodiment of the present invention, a STT MRAM using Fe:MoS2 also requires less energy by virtue of the relatively small quantity of iron atoms. These factors make spin-polarized currents able to be used even when the device is scaled down.

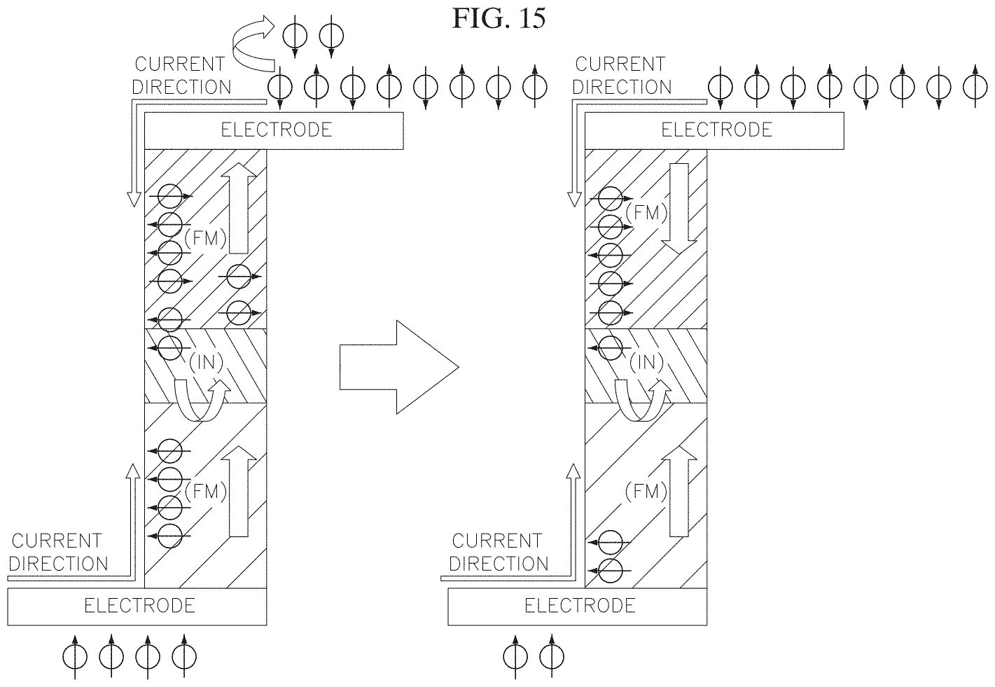

Parallel magnetization of one STT-MRAM cell is illustrated schematically in FIG. 14. Charges pass through the fixed FM first, and then the spin-polarized charges pass through the free FM with magnetization parallel to the spin of the charges. In contrast, antiparallel magnetization of a single cell is shown for two different scenarios in FIG. 15: wherein the magnetic moment directions of the fixed and free layers are the same, resulting in the current flowing well (left), and wherein the magnetic moment directions of the fixed and free layers are different, resulting in an increase in resistance (right). In this embodiment, charges pass through the free FM first. Partially spin-polarized current flows are shown, wherein up is the majority current and down is minority current in the illustrated examples. The majority current passes through the fixed FM, and the minority current bounces back to the free FM. In this manner, minority charges accumulate and change the magnetization of the free FM. Thus, the majority charges change (i.e., from up to down). To this end, the applied current flow is reduced.

The fabrication methods for integrating Fe:MoS2 into the device architecture have generally been well-established. To fabricate 2D STT MRAM, the bottom electrode and bottom insulator can be fabricated via standardized lift-off photolithography and sputtering. The free layer (e.g., Fe:MoS2 monolayers) can be transferred onto the surface with polymer-based methods which have been well-established in the past 20 years.

The fixed layer, insulator, and free layer structure can be easily fabricated and integrated into current STT MRAM structures via replacing the top free layer with the inventive 2D ferromagnetic semiconductor monolayer.

### Example 1

### Synthesis and Characterizations of Fe:MoS₂ Monolayers

MoS₂ monolayers were synthesized via LPCVD. Prior to growth, a thin MoO₃ layer was prepared using physical vapor deposition (PVD) of MoO₃ onto a Si substrate with 300 nm-thick thermal oxides. Another SiO₂/Si substrate contacted the MoO₃-deposited substrate face-to-face. Fe:MoS₂ monolayers were grown onto the SiO₂/Si substrate. The Fe doping was achieved in the following sequence: Fe₃O₄ particles were evenly cast onto the SiO₂/Si substrate before contacting the MoO₃-deposited substrate. To ensure a uniform distribution of Fe₃O₄ particles, the substrate was washed using deionized (DI) water, so that a thin layer of water was created on the SiO₂ surface, prior to applying the Fe₃O₄ particles. The substrate was then annealed at 110° C. for 5 min on a hot plate. For the growth, the furnace was heated up with a ramping rate of 18° C. min⁻¹ and held for 15 min at 850° C. During the heating procedure, an argon gas (30 s.c.c.m.) was supplied at 300° C. and, subsequently, a hydrogen gas (15 s.c.c.m. of) was delivered at 760° C. Sulfur was supplied when the furnace temperature reached 790° C. After the growth, a few millimeters size of Fe: MoS2 monolayers were obtained.

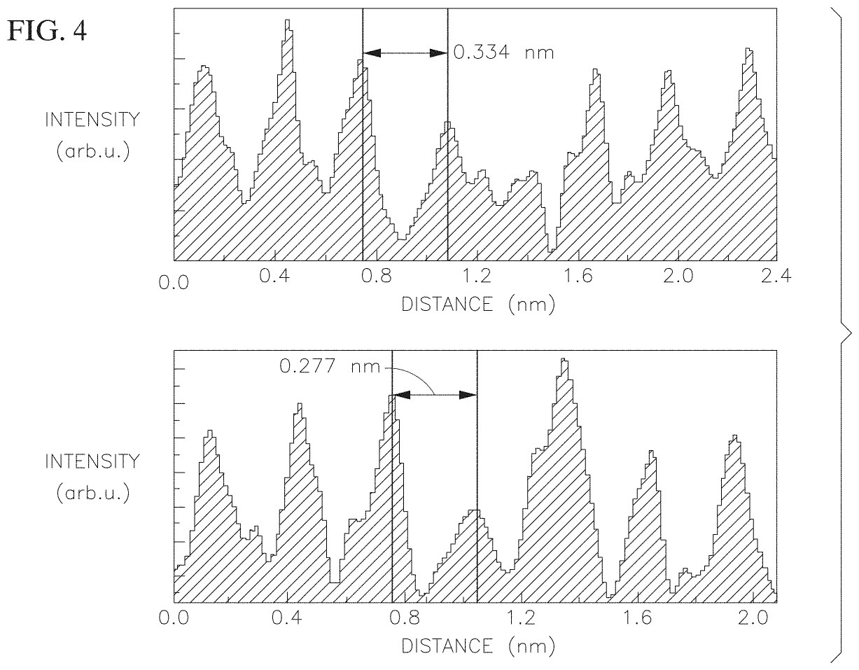

As explained above, the in-situ Fe doping of monolayer MoS2 was realized by growing MoS2 with Fe3O4 via the LPCVD contact-growth method. To eliminate the effects of local disorders in the substrate, both as-grown MoS2 and Fe:MoS2 monolayers were encapsulated into thin-film hBN. A scanning electron microscopy (SEM) image of Fe:MoS2 monolayers was obtained, and triangular island-like domains were observed, which are typical for similar MoS2-CVD growth techniques. As substitution of Fe atoms at Mo sites is thermodynamically favorable, Fe dopant atoms replace Mo host atoms in the MoS2 crystal. To gain further insight into the atomic structure of the Fe:MoS2 monolayer, high-angle annular dark-field scanning transmission electron microscopy (HAADF-STEM) was employed. Compared with Mo (Z=42) atoms, Fe (Z=26) has ˜40% smaller atomic number. As the magnitude of the forward-scattered electron intensity is dependent on the atomic number, it is expected that Fe atoms produce lower relative intensity, which is clearly visible for the substitutionally doped Fe atoms in the STEM image. The corresponding STEM intensity scan in FIG. 4 verifies the intensity ratio of 0.38, which is consistent with the atomic number ratio and previously reported observations. A broad Fe 2p3 peak from Fe:MoS2 monolayers was identified using X-ray photoelectron spectroscopy (XPS) and the atomic concentration was calculated as 0.3˜0.5%. Limited tunability was observed in doping concentration in the synthesis, which is attributed to the high energy barrier to replace Mo by Fe.

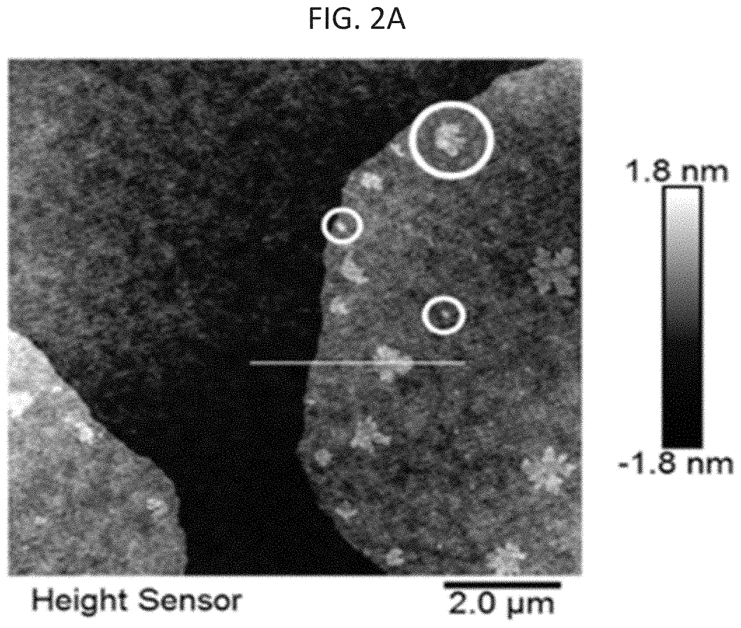

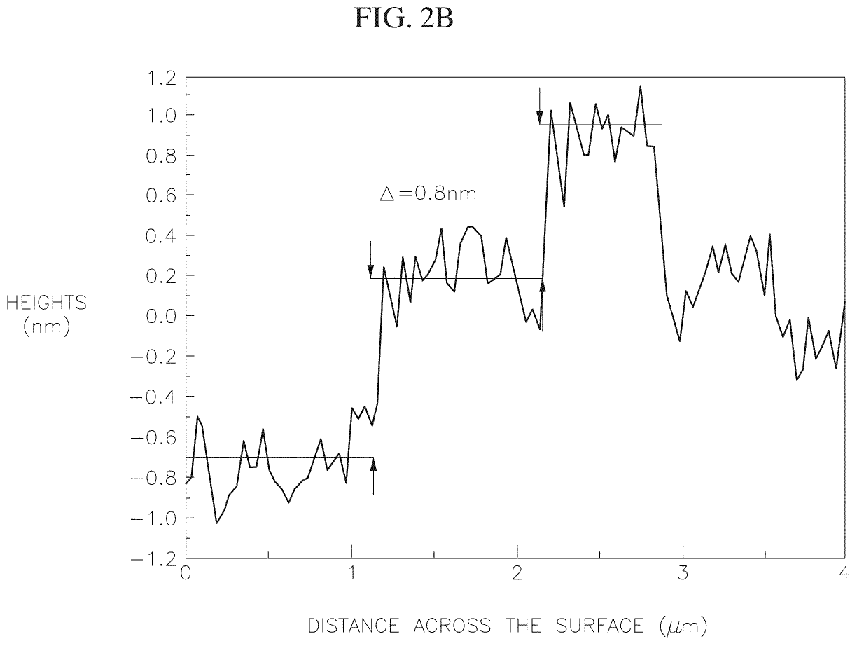

To verify the growth of monolayer Fe:MoS2 domains, the samples were characterized using atomic force microscopy (AFM). The AFM image occasionally showed the onset of the growth of the next layer, (i.e., the bilayer of Fe:MoS2 with its typical snowflake-like pattern). Bilayer growth was further evident from FIG. 2B which shows an identical step height thickness of 0.8 nm, commensurate with the thickness of Fe:MoS2 monolayers (0.8 nm) and bilayers (1.6 nm). The AFM images further confirm that, after wet cleaning and thermal annealing, the surface of Fe:MoS2 is free from any potential residual Fe3O4 particles from the doping process.

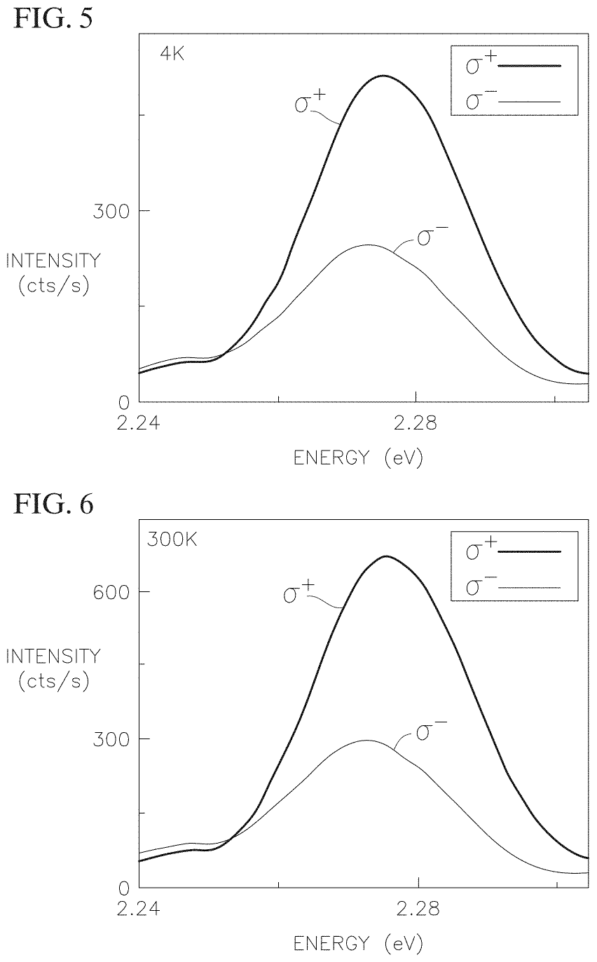

Evolution of PL intensity as a function of temperature for Fe:MoS₂ and MoS₂ monolayers are shown in FIGS. 5 and 6, respectively. A well-documented A-exciton peak at ˜1.92 eV was observed in MoS₂ monolayers at 4 K. In addition, an abundant asymmetric peak at ˜1.8 eV was observed, which is caused by anion di-vacancies acting as point defects. This novel characterization technique for semiconducting 2D ferromagnets makes use of nitrogen-vacancy-center magnetometry by directly determining the local magnetic field strength, 0.5±0.1 mT.

### Magnetic Characteristics of Fe:MoS₂ Monolayers

Transition metal ions show unequal amounts of light absorption when excited with left- and right-handed circular polarizations. At the atomic level, the light absorption is closely related to the magnetically induced Zeeman shifts. Therefore, performing MCD spectroscopy can give insights into the magnetic properties of the material. FIGS. 5 and 6 show that the Fe-related emission shows a strong CD (ρ≈40%) at both 4 K and RT. Given that the transition metals' luminescence loses its CD above the Curie temperature T_{C} 36, observation of a strong CD at 300 K suggests that Fe:MoS₂ remains ferromagnetic at RT.

### CONCLUSION

In situ substitutional doping of Fe atoms in MoS₂ monolayers via LPCVD has been demonstrated. The presence of Fe atoms in the MoS₂ lattice was verified using STEM and Raman spectroscopy. PL spectroscopy revealed an unambiguous Fe-related emission at 2.28 eV in Fe:MoS₂ monolayers, which is stable up to RT. These findings extend the class of available ferromagnetic van der Waals materials with ferro-magnetism at or above RT and open opportunities towards applications such as on-chip magnetic manipulation in quantum information science or in minimizing bit storage in spintronics.

It will be understood that the embodiments described herein are merely exemplary and that a person skilled in the art may make many variations and modifications without departing from the spirit and scope of the invention. All such variations and modifications, including those represented in FIG. 2, are intended to be included within the scope of the present invention.

1-7. (canceled)

8. A method for making a semiconductor material, comprising the steps of: growing a two-dimensional transition metal dichalcogenide monolayer on a substrate; and simultaneously adding a dopant to said monolayer while said monolayer is being grown on said substrate.

9. The method of claim 8, wherein said dopant is iron.

10. The method of claim 8, wherein said transition metal dichalcogenide monolayer comprises molybdenum disulfide.

11. The method of claim 8, wherein said substrate comprises silicon.

12. The method of claim 8, further comprising the step of heating said substrate.

13. The method of claim 12, wherein sulfur gas is applied to said substrate during said heating step.

14. The method of claim 8, wherein said transition metal dichalcogenide monolayer is atomically thin.

15. The method of claim 8, wherein said substrate comprises sapphire.

16. A method for making a semiconductor material, comprising the steps of: growing a two-dimensional transition metal dichalcogenide monolayer on a substrate; and simultaneously adding a dopant to said monolayer while said monolayer is being grown on said substrate by casting a dopant source on a surface of another substrate.

17. The method of claim 16, further comprising the step of annealing said another substrate.

18. The method of claim 17, further comprising the step of depositing said transition metal dichalcogenide monolayer on said substrate.

19. The method of claim 18, wherein said depositing step is conducted with low-pressure chemical vapor deposition.

20. The method of claim 19, wherein said low-pressure chemical vapor deposition is performed with at least one thermal oxide.

21. The method of claim 17, further comprising the step of contacting said substrate with said surface of said another substrate.

22. The method of claim 16, wherein said another substrate comprises silicon.

23. The method of claim 16, wherein said another substrate comprises sapphire.

24. (canceled)

25. (canceled)

26. A magnetic tunnel junction, comprising: a free layer made from a semiconductor material, said semiconductor material comprising a two-dimensional, iron-doped transition metal dichalcogenide monolayer; a fixed layer of ferromagnetic material; and a tunnel barrier interposed between said free layer and said fixed layer of ferromagnetic material.

27. The magnetic tunnel junction of claim 26, wherein said free layer has a magnetic state.

28. The magnetic tunnel junction of claim 27, wherein said free layer is configured to store information in its said magnetic state.

29. The magnetic tunnel junction of claim 28, wherein said fixed layer is configured to provide a reference frame to facilitate reading and writing of said information.

30. The magnetic tunnel junction of claim 29, wherein said information is adapted to be read via the TMR effect

31. The magnetic tunnel junction of claim 29, wherein said information is adapted to be written via the STT effect.
